(19) United States
(12) Patent Application Publication
(10) Pub. No.: US 2021/0389126 A1
(43) Pub. Date: Dec. 16, 2021

(54) Surface Profile Mapping for Evaluating III-N Device Performance and Yield

(71) Applicant: The Government of the United States of America, as represented by the Secretary of the Navy, Arlington, VA (US)

(72) Inventors: James C. Gallagher, Alexandria, VA (US); Travis J. Anderson, Alexandria, VA (US); Jennifer K. Hite, Arlington, VA (US); Karl D. Hobart, Alexandria, VA (US)

(73) Assignee: The Government of the United States of America, as represented by the Secretary of the Navy, Arlington, VA (US)

(21) Appl. No.: 17/345,012

(22) Filed: Jun. 11, 2021

Related U.S. Application Data
(60) Provisional application No. 62/705,129, filed on Jun. 12, 2020.

(51) Int. Cl. G01B 11/30

(52) U.S. Cl. CPC G01B 11/303; H01L 29/34

(57) ABSTRACT

An improved method for evaluating GaN wafers. RMS analysis of wafer heights obtained by optical interferometric profilometry is combined with an extreme Studentized deviate (ESD) analysis to obtain a map of the wafer surface that more accurately identifies areas on the surface of a GaN wafer having defects that making those areas unsuitable for fabrication of a vertical electronic device thereon such as bumps and/or pits that can lower the breakdown voltage, increase the on-resistance, and increase the ideality factor.

### CROSS-REFERENCE

This application is a Nonprovisional of and claims the benefit of priority under 35 U.S.C. § 119 based on U.S. Provisional Patent Application No. 62/705,129 filed on Jun. 12, 2020. The Provisional application and all references cited herein are hereby incorporated by reference into the present disclosure in their entirety.

### FEDERALLY-SPONSORED RESEARCH AND DEVELOPMENT

The United States Government has ownership rights in this invention. Licensing inquiries may be directed to Office of Technology Transfer, US Naval Research Laboratory, Code 1004, Washington, D.C. 20375, USA; +1.202.767.7230; techtran@nrl.navy.mil, referencing Navy Case #113217.

### TECHNICAL FIELD

The present disclosure relates to GaN substrates and epitaxial layers, particularly to evaluation of the surface of such substrates and epitaxial layers to predict device performance and enable an estimate of the yield of devices that can be fabricated on such substrates.

### BACKGROUND

As a wide bandgap semiconductor, GaN and GaN-based technologies are important in the development of next-generation electronics due to its high breakdown field, high mobility, and chemical and thermal stability.

It is well known that GaN-based technology should theoretically lead to the development of electrical devices having higher quality than can be achieved using Si or SiC due to due to GaN's larger Baligia figure of merit, which is a figure of merit for power switching devices. Fundamentally this means that GaN devices will exhibit a lower specific ON-resistance compared to a Si or SiC device rated at the same voltage.

GaN-based vertical electronic devices such as P-i-N diodes, Schottky barrier diodes, junction barrier Schottky (JBS) diodes, current aperture vertical electron transistor (CAVET), p-n junction gated field effect transistor (JFET), and metal oxide semiconductor field effect transistor (MOSFET) are of significant interest for next-generation power switching technology.

The block schematics in FIGS. 1A and 1B illustrate the structures of exemplary vertical devices that can be fabricated on a GaN substrate.

The block schematic in FIG. 1A illustrates an ideal vertical GaN diode comprising a defect-free n+ GaN substrate 101a, an n− GaN epitaxial layer 102 formed on an upper surface of substrate 101a, a P-GaN epitaxial layer 103a formed on an upper surface of n− layer 102a, and P- and N-ohmic contacts 104a and 105a formed on the top and bottom of the device. In the absence of material defects, and with proper device design such as doping levels and edge termination, as described above, the device will exhibit lower specific ON-resistance and other improved properties as compared to devices based on Si.

However, commercially available GaN substrates are not consistent across their entire surface. See J. C. Gallagher et al., “Long range, non-destructive characterization of GaN substrates for power devices,” J. Cryst. Growth. 506 (2019) 178-184. The inconsistent quality of such substrates can decrease the quality of homoepitaxial films deposited thereon, thus degrading the performance of vertical devices fabricated on such substrates. See J. K. Hite, et al., “Influence of HVPE substrates on homoepitaxy of GaN grown by MOCVD,” J. Cryst. Growth 498 (2018) 352-356 (Hite 2018); and J. K. Hite, et al., “Effect of Surface Morphology on Diode Performance in Vertical GaN Schottky Diodes,” ECS J. Solid State Sci. Technol. 6 (2017) S3103-S3105 (Hite 2017).

The block schematic in FIG. 1B illustrates aspects of an actual, i.e., non-ideal, vertical GaN diode in accordance with the prior art. Such actual structures can include non-uniformities and/or defects in the n+ GaN material forming substrate 101b, extended defects in n− GaN epilayer 102b, and an uneven surface morphology in the topmost p-GaN epi layer 103b resulting from the defects of the underlying layers and/or from irregularities in the offcut angle of the topmost layer. These defects can affect the way in which top and bottom p- and n-ohmic contacts 104b and 105b contact the structure, which in turn can alter the surface and internal electric field distribution, leading to excessive leakage current, premature breakdown, or poor reliability of a device fabricated on such a substrate. While offcut angles in the substrate can be configured so as to manage device performance, see U.S. Pat. No. 9,368,582 entitled “High Power Gallium Nitride Electronic Using Miscut Substrates,” surface defects in the substrate still limit the number, type, and size of devices that can be manufactured thereon.

The effect of surface defects on device performance is illustrated by the current leakage map in FIG. 2, which shows the results of an investigation by Isik Kizilyalli et al. of the effects of surface morphology on reverse vertical current leakage of a GaN chip at −1000V. As can be seen from the FIGURE, region 201 of the chip has a rough surface and exhibits a measured leakage current of more than 100 μA, while region 201 of the chip has a relatively smooth surface, and exhibits a much smaller leakage current of less than 1 μA. See Isik C. Kizilyalli, et al., “Reliability studies of vertical GaN devices based on bulk GaN substrates,” Microelectronics Reliability 55 (2015) 1654-1661. The high leakage current density is not acceptable for device yield, as there will be excessive localized heating that will produce unstable device behavior under electrical stress.

Similar results have been reported on wafers that are known to be highly non-uniform as part of ongoing evaluation efforts at the U.S. Naval Research Laboratory (NRL). Wafers that are proven to be uniformly conductive initially are predicted to exhibit improved reliability due to the mitigation of impurities that cause highly compensated insulating regions. These are a source of high non-uniform electric fields in the device that can lead to impurity diffusion and defect generation.

Thus, it is desirable to have a way to quickly and easily identify the regions of a GaN substrate that are likely to experience significant current leakage, since devices fabricated on such regions will suffer from subpar performance. Device yield will be greatly improved by mapping incoming wafers to identify the uniformly conductive regions suitable for device fabrication and appropriate lots of wafers prior to costly epitaxial growth and processing.

However, while methods for screening wafers to identify such defects or irregularities exist such as cathodoluminescence imaging or two photon photoluminescence, many of them are labor-intensive and cumbersome, while others do not examine the conductivity of the sample, which is especially critical in vertical device performance. See Tomoyuki Tanikawa et al., “Three-dimensional imaging of threading dislocations in GaN crystals using two-photon excitation photoluminescence,”2018 Appl. Phys. Express 11 031004; K. Fleischer et al., “Depth profiling of GaN by cathodoluminescence microanalysis,” Appl. Phys. Lett. 74, 1114 (1999); R. E. Stahlbush et al., “Basal plane dislocation reduction in epitaxy by growth interruptions,” Appl. Phys. Lett. 94, 041916 (2009); James C. Gallagher et al., “Effect of GaN Substrate Properties on Vertical GaN PiN Diode Electrical Performance,” Journal of Electronic Materials (2021); see also Gallagher et al., supra, and Hite 2017, supra.

One method that recently has been developed by the inventors of the present invention uses Raman spectroscopy to examine GaN wafers and evaluate their surfaces to identify wafers and areas on wafers that are most suitable for device fabrication. See U.S. Patent Application Publication No. 2020/0400578 entitled “Mapping and Evaluating GaN Wafers for Vertical Device Applications.”

Additional methods of characterizing and screening GaN wafers, e.g., in cases where Raman spectroscopy may not be available, may also be desirable.

For example, Kizilyalli has developed a method which uses optical spectroscopy to examine the surface of a wafer. See Kizilyalli, supra. The Kizilyalli method evaluates the RMS roughness of the wafer surface to determine whether the RMS roughness falls below a predetermined threshold, typically below 25 nm, corresponding to acceptable wafer smoothness. Though this RMS value is related to the quality of the sample, it is not a universally good measure since it scales with the thickness of the epitaxial layers and the size of devices to be fabricated on the wafer. Results show that for large devices this method tends of overpredict the performance.

### SUMMARY

This summary is intended to introduce, in simplified form, a selection of concepts that are further described in the Detailed Description. This summary is not intended to identify key or essential features of the claimed subject matter, nor is it intended to be used as an aid in determining the scope of the claimed subject matter. Instead, it is merely presented as a brief overview of the subject matter described and claimed herein.

The present invention improves upon the prior art methods for evaluating GaN wafers by combining RMS analysis obtained by optical interferometric profilometry with an extreme Studentized deviate (ESD) analysis to obtain a map of the wafer surface that more accurately identifies areas on the surface of a GaN wafer having defects that make those areas unsuitable for fabrication of a vertical electronic device thereon, such as bumps and/or pits that can lower the breakdown voltage, increase the on-resistance, and increase the ideality factor.

### BRIEF DESCRIPTION OF THE DRAWINGS

FIGS. 1A and 1B are block schematics illustrating aspects of an exemplary ideal vertical GaN diode, in which all of the GaN layers are defect-free (FIG. 1A), and an exemplary actual vertical GaN diode, in which one or more of the GaN layers has one or more defects therein (FIG. 1B).

FIG. 2 is an image illustrating a map of leakage current exhibited by an area of a GaN substrate having a smooth, defect-free surface versus an area of the same substrate that has a rough surface produced by defects within the GaN crystal.

FIGS. 3A and 3B are images illustrating optical interferometric profilometry results of a high-quality GaN wafer (FIG. 3A) and a similar wafer after epitaxial growth (FIG. 3B), showing the presence of defects on the surface of the wafer.

FIGS. 4A and 4B are images showing an exemplary GaN wafer, where the wafer image shown in FIG. 4A is divided into unit cells corresponding to the size of a device that may be fabricated on the wafer (FIG. 4B).

FIG. 5 is an image illustrating the results of an RMS analysis of a GaN wafer, showing where the wafer surface exhibits high RMS values versus low RMS values.

FIGS. 6A-6C illustrate the way in which the surface profile mapping method of the present invention can provide information regarding the surface characteristics of a GaN wafer.

FIGS. 7A and 7B are histogram plots further showing the way in which the surface profile mapping method of the present invention can provide information regarding the surface characteristics of a GaN wafer.

FIG. 8 is a flow chart outlining an exemplary process flow in a method for surface profile mapping and evaluating the surface roughness of a GaN wafer in accordance with the present invention.

FIGS. 9A-9C are optical profilometry maps showing a sample RMS scan of a low-quality GaN wafer (FIG. 9A), an RMS scan showing areas of the wafer having bumps and/or pits (FIG. 9B) and an RMS scan showing areas having excessive defects (“failures”) (FIG. 9C).

FIGS. 10A-10C are optical profilometry maps showing a sample RMS scan of a high-quality GaN wafer (FIG. 10A), an RMS scan showing areas of the wafer having bumps and/or pits (FIG. 10B) and an RMS scan showing areas having excessive defects (“failures”) (FIG. 10C).

FIGS. 11A and 11B illustrate the results of analysis of two GaN wafers and simulated devices of various sizes under the prior art Kizilyalli method and the surface profile mapping method in accordance with the present invention.

FIG. 12A is a schematic showing the rate at which devices fail this inventions method using a Generalized ESD test (orange), the prior art's method (yellow) and both (red). FIG. 12B is a histogram plot showing the percentage failure rates from FIG. 12A.

FIG. 13 is a plot illustrating the performance of three diodes: one that fails because of high leakage, one that fails because of low turn on voltage, and one that passes.

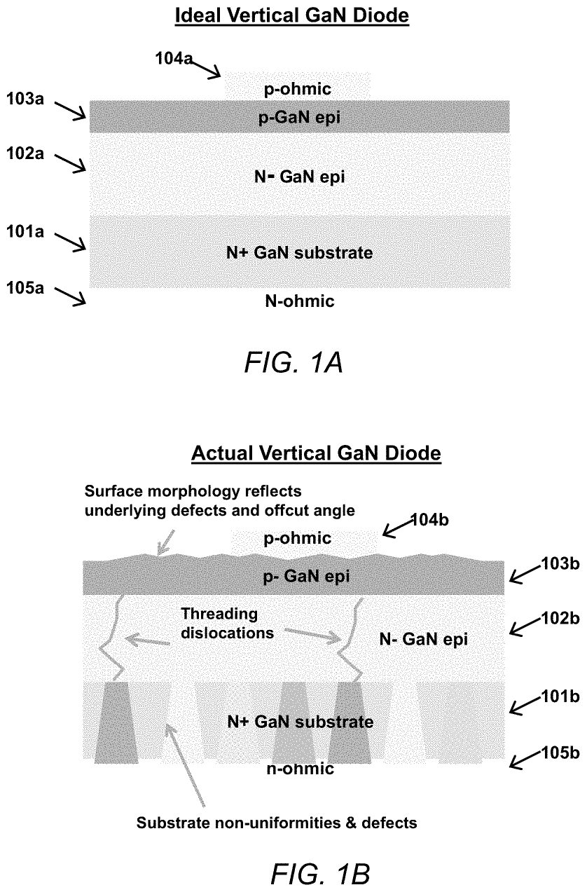

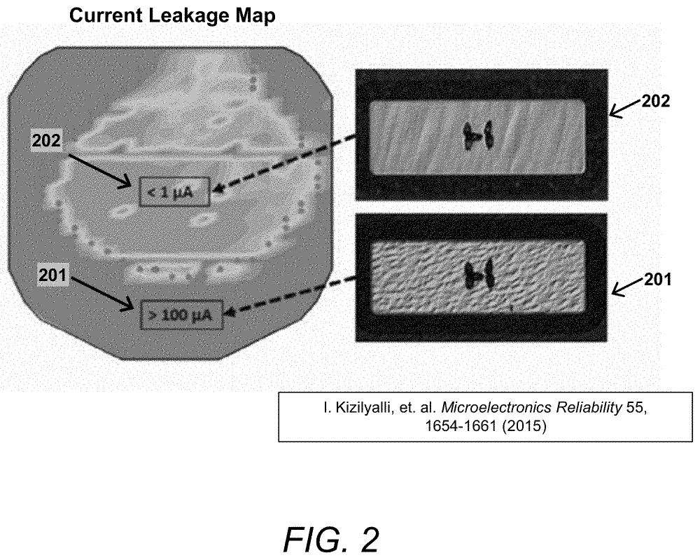

### DETAILED DESCRIPTION

The aspects and features of the present invention summarized above can be embodied in various forms. The following description shows, by way of illustration, combinations and configurations in which the aspects and features can be put into practice. It is understood that the described aspects, features, and/or embodiments are merely examples, and that one skilled in the art may utilize other aspects, features, and/or embodiments or make structural and functional modifications without departing from the scope of the present disclosure.

The present disclosure provides a technique for evaluating GaN substrates and epitaxial layers to predict device performance and enable an estimate of the device yield.

The method of the present invention provides an improvement over the prior art Kizilyalli optical profilometry method for analyzing the surface roughness of a GaN substrate. As noted above, Kizilyalli's method looks only at the RMS roughness of the sample to evaluate whether it falls below a predetermined threshold, typically below 25 nm. Though this RMS value is related to the quality of the sample, it is not a universally good measure since it scales with the thickness of the epitaxial layers and the size of devices to be fabricated on the wafer. Results show that for large devices this method tends of overpredict the performance.

As described in more detail below, the present invention improves upon the Kizilyalli method by combining RMS analysis obtained by optical interferometric profilometry with an extreme Studentized deviate (ESD) analysis to more accurately identify areas on the surface of a GaN wafer having bumps and/or pits that can lower the breakdown voltage, increase the on-resistance, and increase the ideality factor, making those areas unsuitable for fabrication of a vertical electronic device thereon.

In this way, the screening technique in accordance with the present invention will help lead to higher yield by avoiding fabrication of devices on unsuitable substrates and will result in improved device performance and reliability compared to GaN devices that may be fabricated on unscreened substrates.

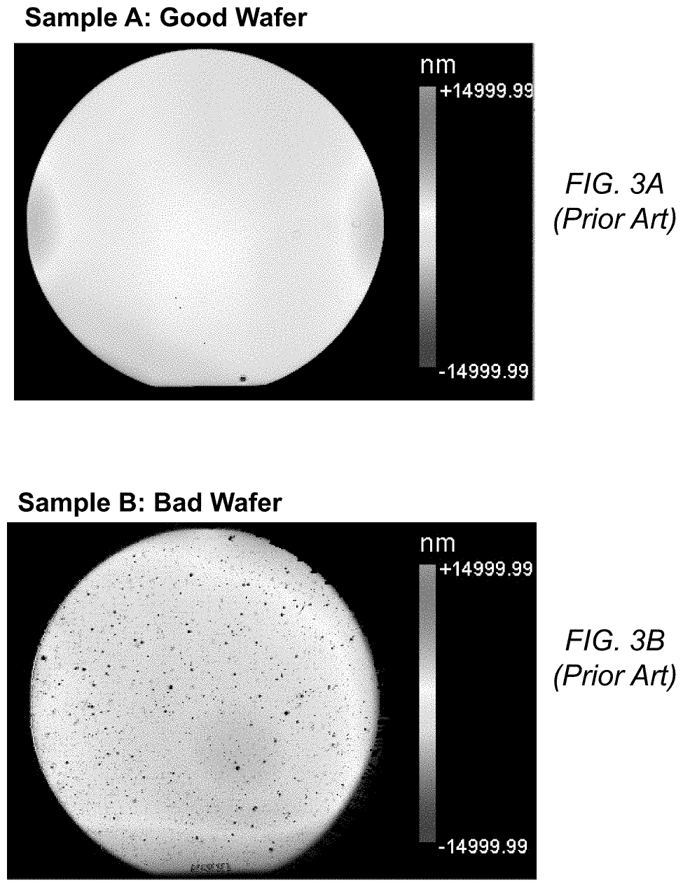

Optical profilometry produces a surface map of a device. The optical profilometry images in FIGS. 3A and 3B show the surface profiles of two GaN wafers, denoted as “Sample A” and “Sample B,” where Sample A is a smooth, bare as-produced GaN substrate wafer and Sample B is a similar GaN wafer after homoepitaxial growth of a GaN drift layer and p-layer. As can be readily seen in FIG. 3B, the Sample B wafer exhibits defects, manifested as bumps and pits on the surface, that were developed during the epitaxial growth. A quantitative analysis of these defects, i.e., a determination of their number and density at various locations on the wafer surface, will help indicate whether the wafer is still suitable for device fabrication with reasonable electrical performance and process yield.

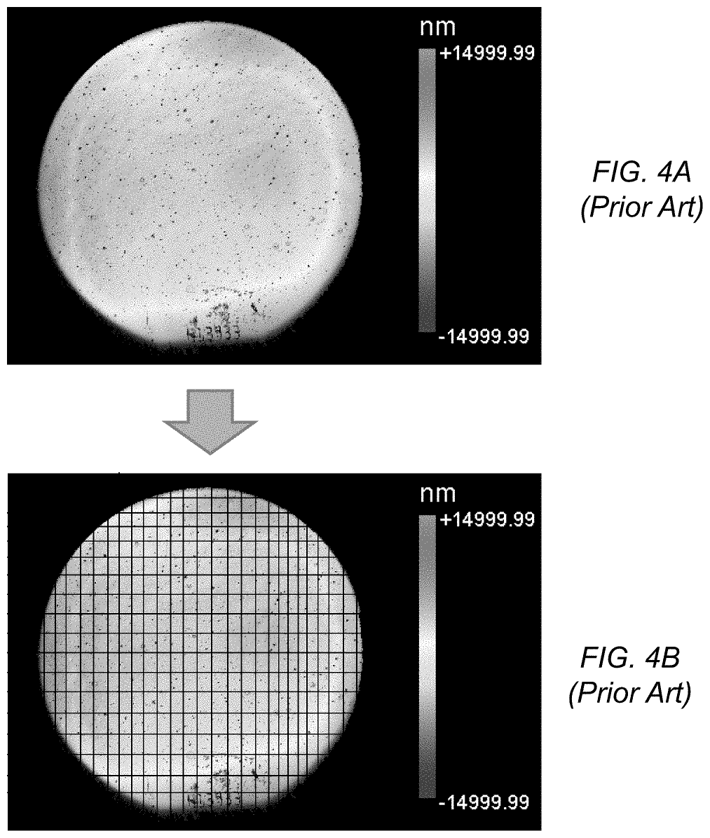

To estimate the yield of a wafer using optical profilometry, the surface maps can be divided into a plurality of predefined areas, also referred to herein as “unit cells,” having a predefined size and/or shape (e.g., square or rectangular), as shown in FIGS. 4A and 4B. In many cases, the unit cells will correspond to the size/shape of a device or devices that may be fabricated on the wafer, but any other criteria can be used to determine the size and/or shape of the unit cells. In the exemplary case illustrated in FIGS. 4A and 4B, the surface map of a 2-inch GaN wafer such as that shown in FIG. 4A is divided into a plurality of 325×325 μm-sized areas as shown in FIG. 4B. Once the surface map is so divided, an initial analysis of the wafer can be obtained by performing optical profilometry of the surface, which obtains a measure of the RMS roughness of the surface in each bin.

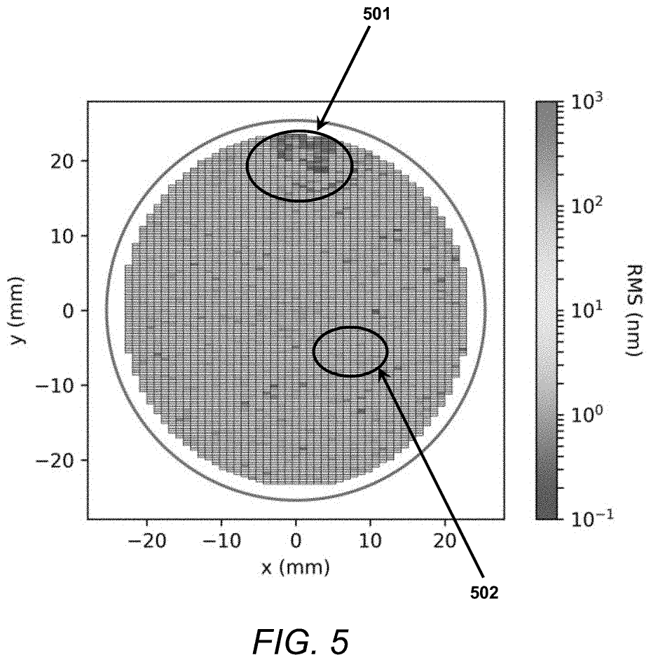

The results of an exemplary optical profilometry analysis is shown in FIG. 5, where the RMS value for the height of the wafer in each unit cell is indicated by the shading in the RMS map shown in the FIGURE. Higher positive RMS values correspond to a greater number of bumps on the surface, lower negative values correspond to a greater number of pits, and values close to 10¹ correspond to smooth surfaces. For example, region 501 shown in FIG. 5 has unit cell areas with an RMS value on the order of about 10³ nm and so has areas with a rough, bumpy surface that is unsuitable for device fabrication, while most of the unit cells in region 502 have an RMS value of 10¹, indicating that much of the area in that region of the wafer is smooth, without excessive bumps or pits, and so is suitable for fabrication of a vertical devices thereon.

However, using RMS roughness alone to evaluate the roughness of a GaN surface is not sufficient. RMS typically increases as more evaluation points are added, thus the RMS values corresponding to bumps and/or pits need to be adjusted with device size. In addition, RMS analysis doesn't necessarily detect all of the types of defects on the surface that can cause devices to fail failure.

The present invention improves on this analysis by combining optical profilometry with generalized extreme Studentized deviate (ESD) analysis to better identify areas having excessive bumps/pits and to better determine the size and placement of devices that can be fabricated on a wafer given the characteristics of its surface.

The generalized ESD is a statistics algorithm that can be used to detect multiple outliers in a data distribution that approximately follows a Gaussian distribution. It works well In this test, the term

$${R}_{i} = \frac{{max}_{i} \vert {x}_{i} - \overline{x} \vert}{σ}$$

is computed, where xᵢ is the datum of interest, \tilde{x} is the mean and σ is the standard deviation. Additionally, a critical level

$${λ}_{j} = \frac{( n - j ) {t}_{p , n - j - 1}}{\sqrt{( n - j - 1 + {t}_{p , n - j - 1}^{2} )} ( n - j + 1 )}$$

computed, where j is the number of observations removed, and t_{p,n} is the value of the 100p percentage points of the t distribution with

$$p = 1 - \frac{α}{2 ( n - j + 1 )} ,$$

where alpha is specified by the user and represents the probability of the point being outside the t distribution. The t distribution percentage points needs to be evaluated numerically and can be looked up on a table. See NIST Engineering Statistics Handbook, “1.3.6.7.2, “Critical Values of the Student's t Distribution,” available at https://www.itl.nist.gov/div898/handbook/eda/section3/eda3672.htm. The data which maximizes the Rᵢ are removed and the values are recomputed. This process repeats until a user specified number of points (in our case about 10% of the total number of points). The number of outliers in the data is the maximum j value which Rᵢ>λⱼ. See NIST Engineering Statistics Handbook, “1.3.5.17.3, Generalized ESD Test for Outliers,” available at https://www.itl.nist.gov/div898/handbook/eda/section3/eda35h3.htm. Many software packages exist that can perform this test, including the open source PyAstronomy.pyasl package.

While ESD analysis is commonly used by data scientists to remove outlying values from data sets, it is not well known in the semiconductor physics community and has not previously been considered to be of use in analyzing the surface characteristics of a semiconductor wafer.

As used in the present invention, ESD analysis determines whether the RMS height values in a particular, defined area of a semiconductor wafer surface fall within a Gaussian distribution of values, such that the RMS values that fall outside this Gaussian distribution can be used to identify areas of the surface that are unsuitable for device fabrication. In the context of the RMS height values, the outlier values correspond to bumps and pits caused by major defects on the sample that can cause shorts and prevent devices from turning on. As described below, use of the ESD test in accordance with the present invention is more accurate than the currently used methods at predicting whether a particular region of a semiconductor wafer will produce a good device.

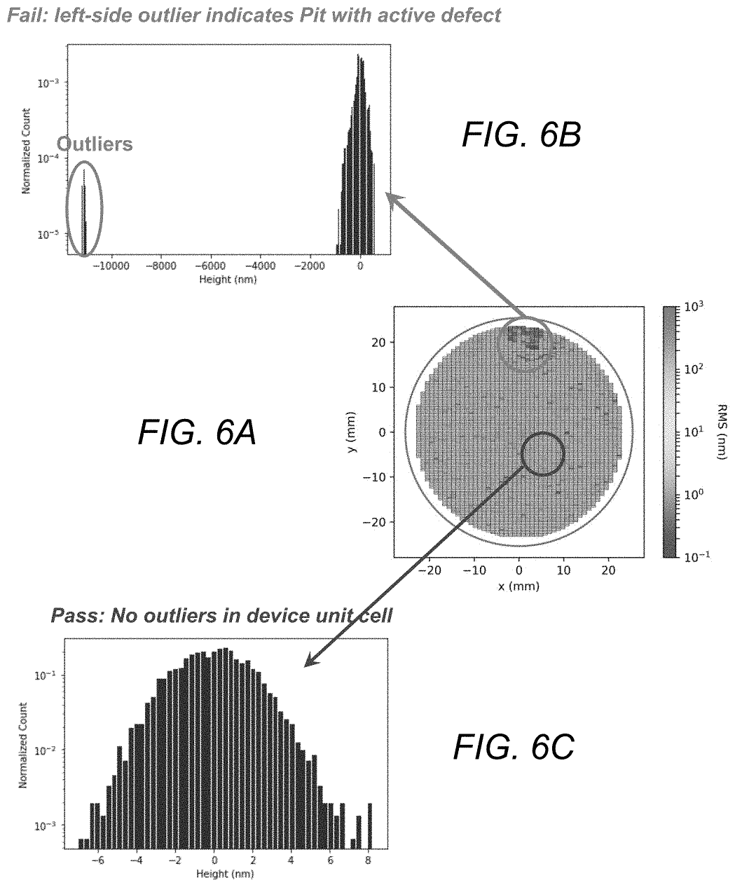

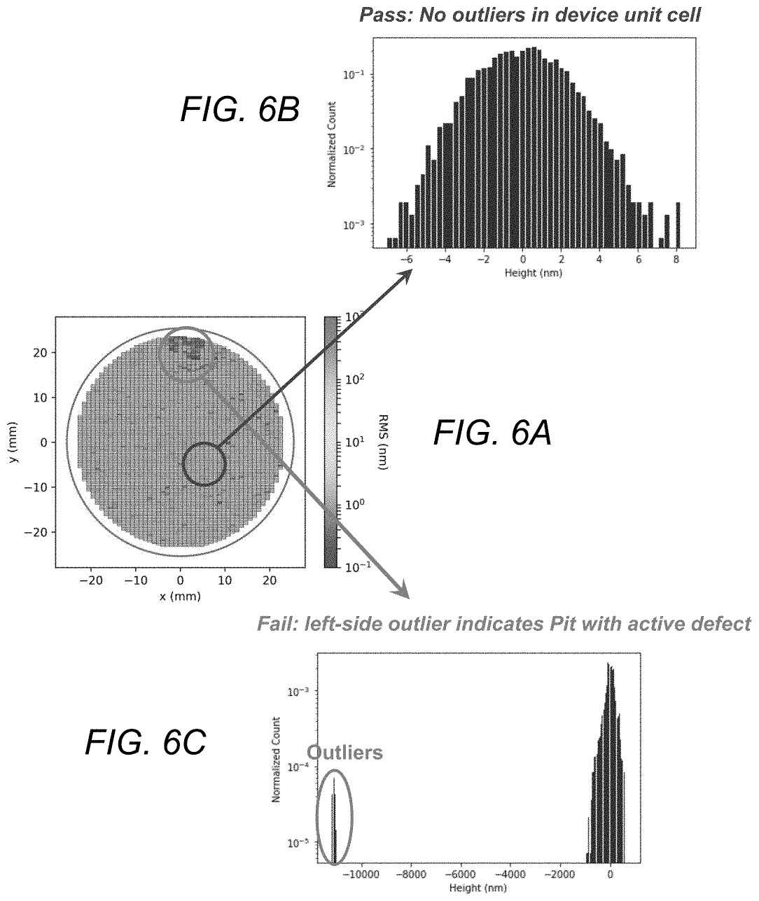

FIGS. 6A-6C illustrate the way in which ESD analysis can be used in combination with RMS analysis to provide information regarding characteristics of a GaN wafer surface. FIG. 6A is the same FIGURE as in FIG. 5, with the same areas as shown in FIG. 5 highlighted. FIGS. 6B and 6C show the results of ESD analysis. The histogram of RMS heights for the area analyzed for FIG. 6B roughly follows a normal, Gaussian, distribution, indicating that that region of the substrate has a smooth surface suitable for device fabrication. In contrast, the histogram of RMS heights in the area analyzed for FIG. 6C shows a outlier values at the far left of the histogram, indicating that the area contains bumps and/or pits resulting from defects in the wafer that can negatively affect device performance, making that area of the wafer less unsuitable for device fabrication.

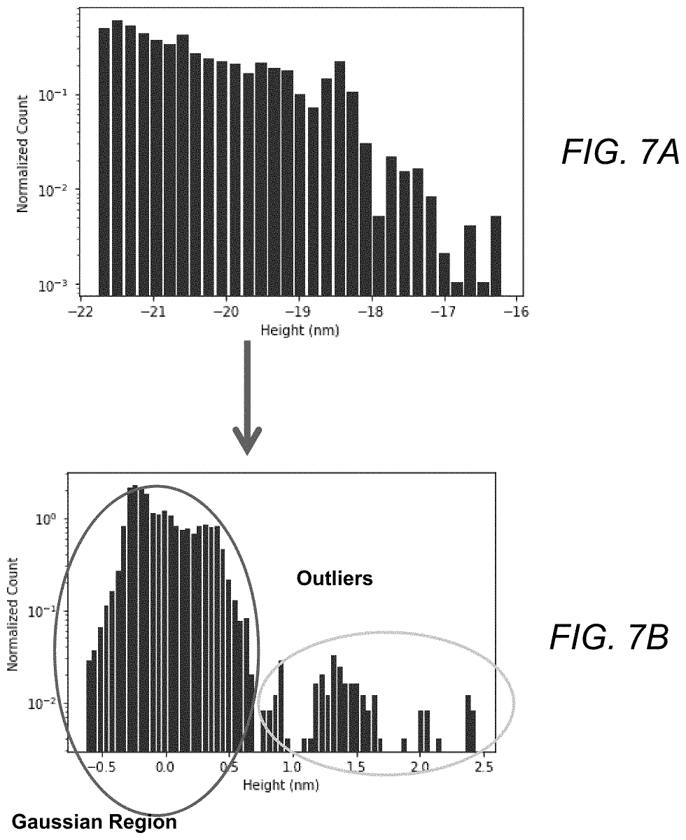

FIGS. 7A and 7B are histogram plots further showing the way in which the surface profile mapping method of the present invention can provide information regarding the surface characteristics of a GaN wafer, with FIG. 7A showing a histogram plot of a region that passes (FIG. 7A) and a region that fails (FIG. 7B) an analysis of surface roughness performed in accordance with the present invention.

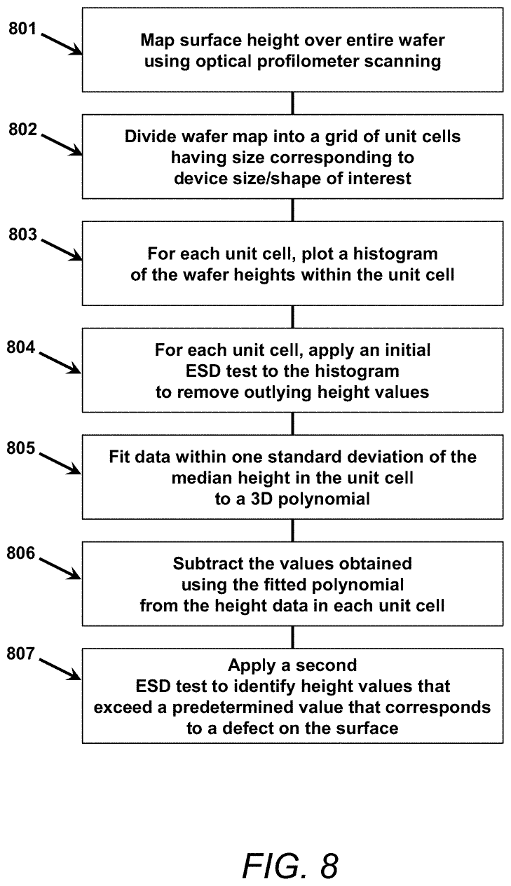

The flow chart in FIG. 8 shows an exemplary process flow that can be used by an processor programmed with appropriate software in a method for mapping and analyzing a GaN wafer in accordance with the present invention. The steps described herein can be performed by any suitable processor programmed with appropriate software and configured to receive and process data relating to the steps of the present invention.

As shown in FIG. 8, in a first step 801, the surface of a GaN wafer is scanned via optical profilometry and the surface height of the entire wafer is mapped. At step 802, the wafer profilometry map is divided into a grid of unit cells, with the size and/or shape of each cell being chosen according to the use to which the wafer is to be put, e.g., according to the size of the vertical electronic devices to be fabricated on the device. In an exemplary case discussed herein, a 2-inch wafer is divided into a grid comprising a plurality of 325×325-μm unit cells, but one skilled in the art will readily understand that the method of the present invention can also be used for wafers of other sizes and/or unit cells of other sizes or dimensions identified on the wafers.

In the next step 803, a histogram of the surface height in each unit cell like the one shown in FIG. 7A is plotted, and at step 804, for each unit cell, an initial ESD test as described above is applied to its corresponding histogram to remove outlying height values in each section of the wafer. Since the intention of this test is to remove points that would interfere with the background subtraction, the cutoff threshold is strict to ensure that any point having a remote possibility of being an outlier is removed. Since the points will be reinserted after the background is fit, it is not essential that all background points are used in the background subtraction at this step.

At step 805, the data of the height values in each unit cell that is within one standard deviation of the median height in the cell is fitted to a 3D polynomial, typically a plane or paraboloid, and at step 806, the height values obtained from the polynomial in step 805 are subtracted from the height values at all data points (including those removed in the initial ESD test and those outside of one standard deviation of the median) within the unit cell to obtain an adjusted histogram of height values such as the one shown in FIG. 7B.

Finally, at step 807, for each unit cell, a second ESD test is applied to the adjusted histogram obtained in step 806 to identify height values that exceed a predetermined threshold, i.e., that are too high (correlating to “bumps”) or too low (correlating to “pits”). Because bumps and pits can cause catastrophic device failures, any defect will result in the subsection of the wafer defined by the unit cell being classified as unsuitable for device fabrication.

By identifying the areas of the wafer that are unsuitable for device fabrication, devices can be fabricated only on areas of the wafer that are suitable, reducing waste in device fabrication and improving overall device performance. Alternatively, by identifying the size of areas that are unsuitable, it may be possible to identify devices of other sizes that can be fabricated in those areas of the wafer, thereby reducing the overall wafer waste.

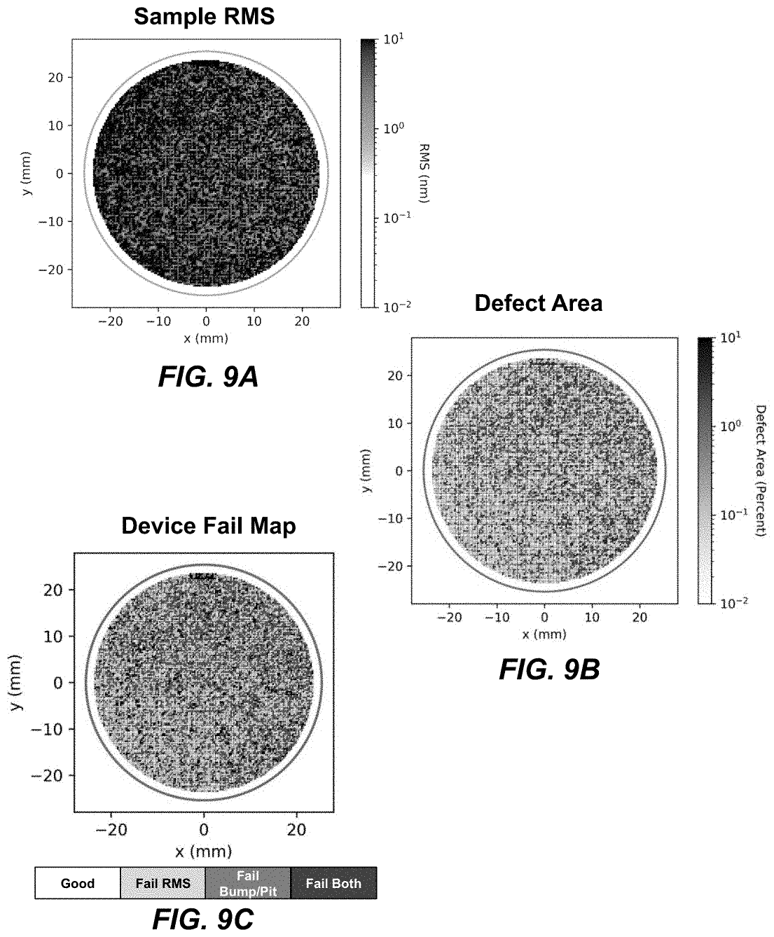

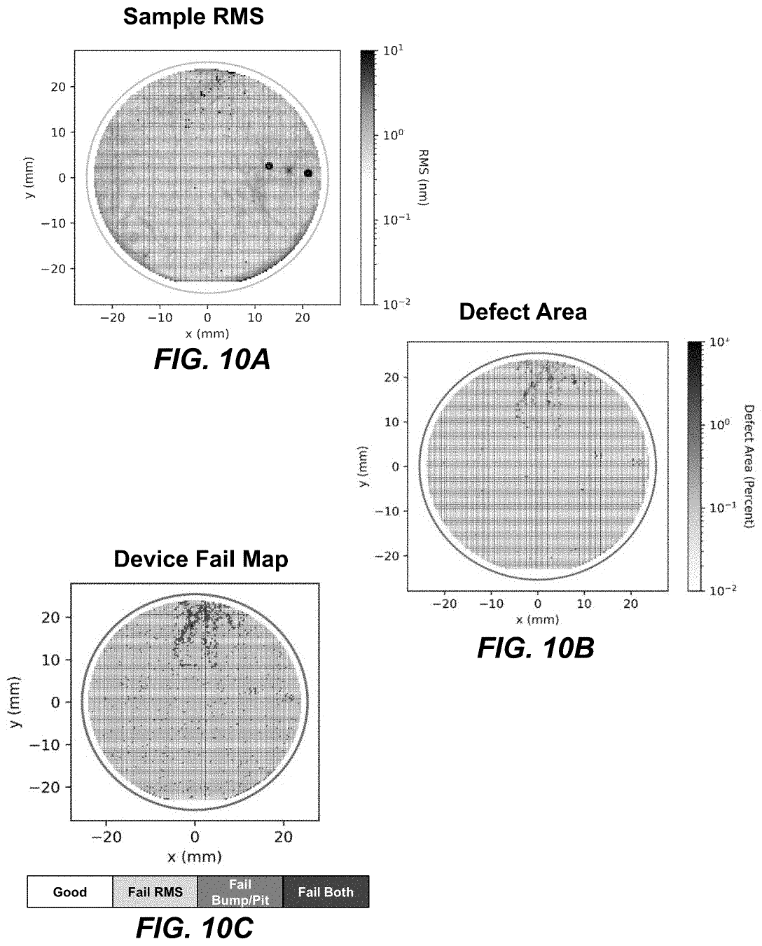

FIGS. 9A-9C are optical profilometry maps showing a sample RMS scan of a low-quality GaN wafer (FIG. 9A), an RMS scan showing areas of the wafer having bumps and/or pits (FIG. 9B) and an RMS scan showing areas having excessive defects (“failures”) (FIG. 9C), while FIGS. 10A-10C show corresponding scans of a high-quality GaN wafer. As can be seen from the maps in FIGS. 10A-10C, the high-quality wafer has very specific, defined defect areas, whereas the low-quality wafer is riddled with bumps and pits, as shown by the maps in FIGS. 9A-9C.

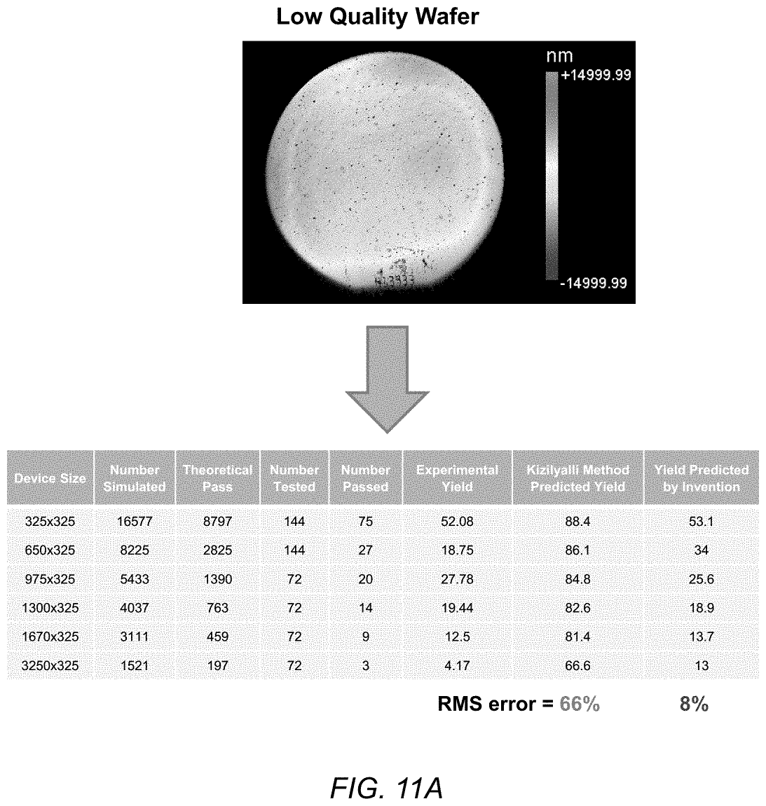

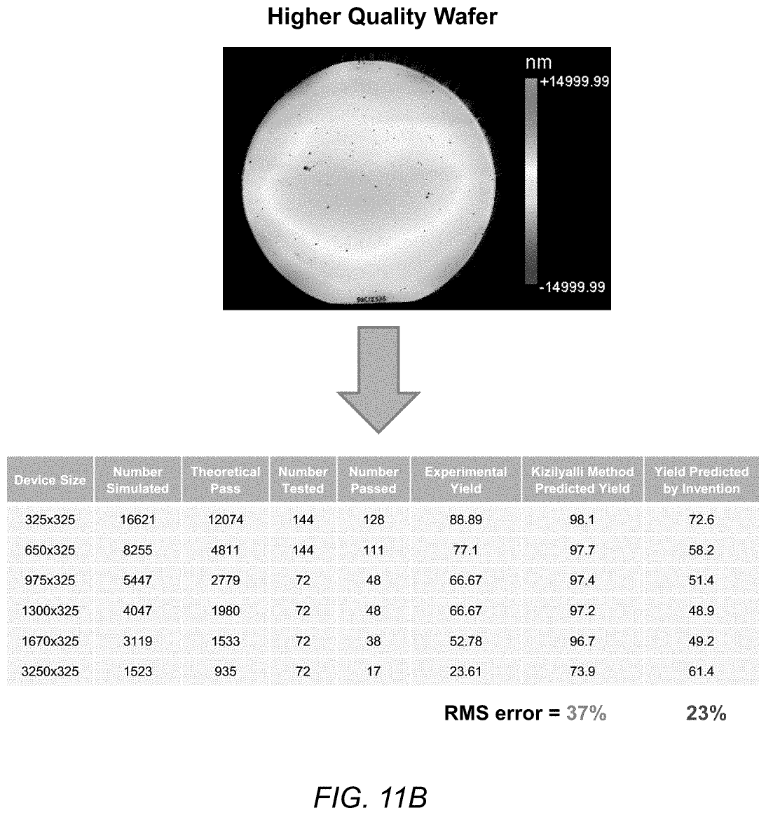

FIGS. 11A and 11B further illustrate the improved wafer analysis provided by the method of the present invention. FIG. 11A shows an optical profilometry image of a low-quality GaN wafer that exhibits a large number of pits and bumps, while FIG. 11B shows a higher-quality GaN wafer that does not exhibit a similarly large number of defects. The tables show that for the high-defect sample examined for FIG. 11A, the RMS error is 8% using the method of the present invention vs. 66% using the Kizilyalli optical profilometry method alone. On low-defect samples, such as the wafer examined for FIG. 11B, the two methods are closer in accuracy, but the method of the present invention still provides a significant improvement over the Kizilyalli method, exhibiting only a 23% error in the predicted yield as opposed to a 37% error in the yield predicted by the Kizilyalli method.

Thus, as shown by the Tables in FIGS. 11A and 11B, the prior art RMS method of Kizilyalli, which is based on a simple threshold criteria, tends to significantly overestimate the device yield of a given GaN wafer, while the method of the present invention is much more accurate.

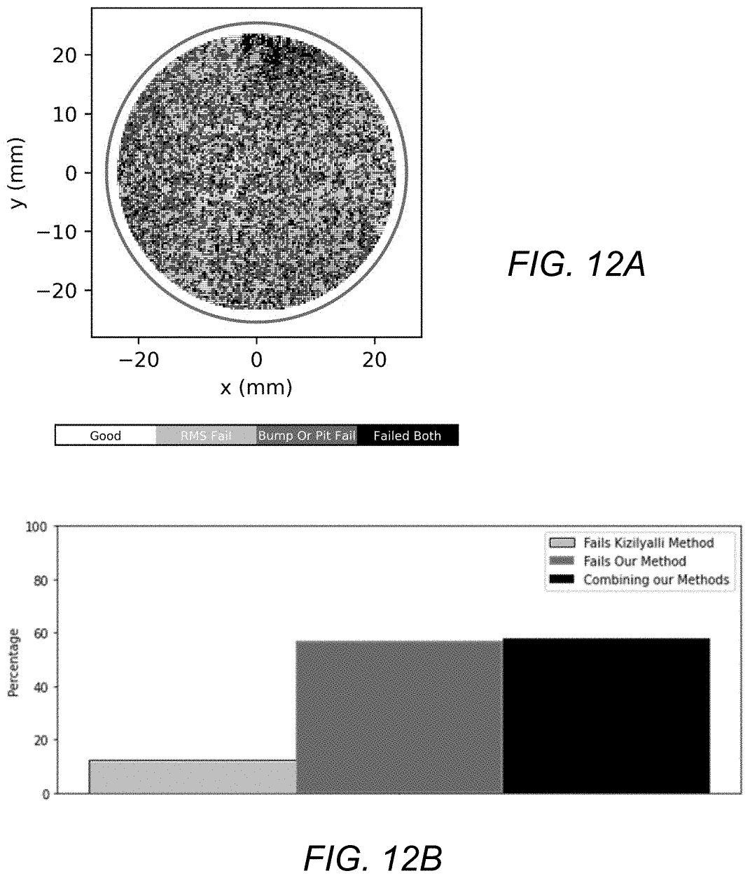

FIGS. 12A and 12B further illustrate the way in which the method of the present invention can be used to analyze the suitability of a wafer for device fabrication. FIG. 12A shows a map of the wafer with regions that pass under both an analysis in accordance with the present invention and a conventional RMS analysis (shown in white), regions that fail only under an RMS analysis (light gray), and regions that fail only under the analysis in accordance with the present invention (dark grey), and areas that fail both methods (black). As shown by the plot in FIG. 12B, less than 20% of the surface area of the wafer was deemed to be suitable for device fabrication under both the conventional RMS analysis and the RMS/ESD analysis of the present invention,

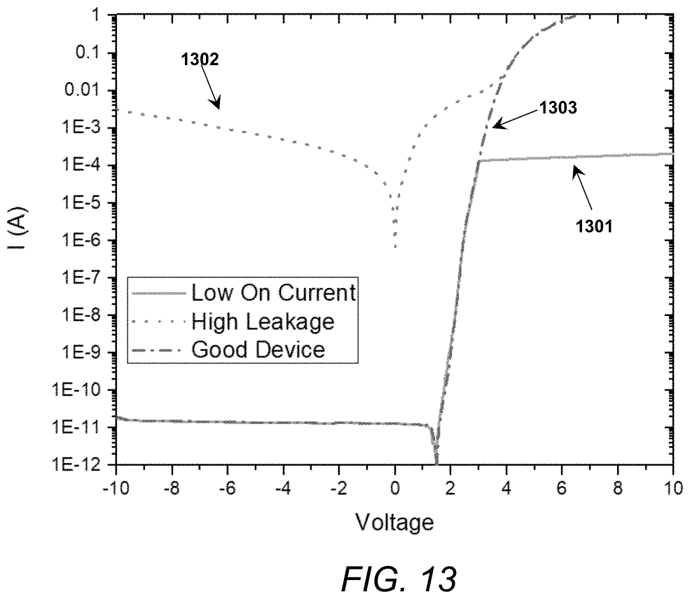

In order to test whether a diode was suitable, a −10 to 10 volt IV sweep was measured and the results were plotted in FIG. 13. In order for a diode to be successful in this test it must have a low reverse leakage current and a high forward current, as shown by the plot in FIG. 13.

Advantages and New Features

Prior art uses a simple and arbitrary threshold criteria, identifying a defective region in any cell with RAZ≥25 nm. Here, the less commonly known generalized ESD method is used to detect defects.

The present invention also collects data on a regular grid equal to the size of a vertical GaN device, to provide spatial mapping relevant to individual devices.

In addition, in contrast to the prior art methods which rely solely on optical profilometry to examine the surface morphology of a GaN wafer, the present invention uses a novel plane subtraction technique to subtract the curvature of the sample without using the defects in the subtraction calculation.

The method of the present invention also uses the failure criteria, as determined by the combination of optical profilometry and ESD testing described above, to estimate the device failure rate on a fully mapped wafer more accurately than is possible using only the optical profilometry done in accordance with the prior art.

This method allows for a greater variety of device sizes to be used since a defect's effect on the RMS is diminished out over long ranges.

Thus, by using ESD analysis in combination with optical profilometry in accordance with the present invention, a more detailed map of the surface morphology of a GaN wafer can be obtained, which can enable device manufacturers to avoid the areas of a wafer that exceeds a predetermined “bumpiness” threshold that would degrade device performance, and/or can enable device manufacturers to tailor the size and placement of electronic devices on the wafer so as to maximize the number and performance of devices manufactured on the wafer. Additionally, it can be used to screen bad wafers to avoid expensive manufacturing on wafers that will not produce high-quality devices.

Although particular embodiments, aspects, and features have been described and illustrated, one skilled in the art would readily appreciate that the invention described herein is not limited to only those embodiments, aspects, and features but also contemplates any and all modifications and alternative embodiments that are within the spirit and scope of the underlying invention described and claimed herein. The present application contemplates any and all modifications within the spirit and scope of the underlying invention described and claimed herein, and all such modifications and alternative embodiments are deemed to be within the scope and spirit of the present disclosure.

What is claimed is:

1. A method for evaluating a surface roughness of a semiconductor wafer, comprising:
using optical profilometry, scanning an upper surface of a semiconductor wafer to obtain an optical profilometry map of surface heights over the wafer;
dividing the optical profilometry map into a grid of unit cells, a size and shape of the unit cells conforming to a size and a shape of at least one electronic device proposed to be fabricated on the semiconductor wafer;
for each unit cell,
plotting a first histogram of surface height values in each unit cell;
conducting a first extreme Studentized deviate test on the surface height values in the first histogram to identify at least one outlying surface height value that exceeds a first predetermined threshold height value;
calculating a median of the surface height values in the unit cell;
identifying a standard deviation of the surface height values and fitting the surface height values that are within the standard deviation to a 3D polynomial to obtain a plurality of fitted height values;
subtracting the fitted height values from all of the height values in the unit cell to obtain a plurality of adjusted surface height values within the unit cell;
plotting a second histogram of the adjusted surface height values; and
conducting a second extreme Studentized deviate test on the adjusted surface height values in the second histogram to identify at least one adjusted surface height value that exceeds a second predetermined threshold height value corresponding to a bump or a pit on the surface of the wafer.
